(19) United States
(12) Patent Application Publication
(10) Pub. No.: US 2012/0188725 A1
(43) Pub. Date: Jul. 26, 2012

(54) ELECTRICAL INSTRUMENT

(75) Inventor: Eiji Masuda, Fukuoka (JP)

(73) Assignee: Kabushiki Kaisha Yaskawa Denki, Kitakyushu-shi (JP)

(21) Appl. No.: 13/349,567

(22) Filed: Jan. 13, 2012

(30) Foreign Application Priority Data
Jan. 24, 2011 (JP) 2011-012113

(51) Int. Cl. H05K 5/00

(52) U.S. Cl. 361/724

(57) ABSTRACT

An electrical instrument includes a casing; a drawer portion in which a connection target to which at least one cable is connected is accommodated and which is configured to be drawable outside the casing; and a cable holding portion configured to hold the cable.

### TECHNICAL FIELD

The present invention relates to electrical instruments.

### BACKGROUND ART

Japanese Patent Application Laid-Open No. 2000-353883 discloses an electrical apparatus in which units, in which electrical instruments composing electric circuits are mounted per predetermined unit, are boarded on a unit boarding frame and are accommodated in a casing. The unit boarding frame is mounted on the front side of the casing so as to be drawable. Further, the unit boarding frame is mounted revolvably so that its front part is brought down when it is drawn out. A cable connected to the electrical apparatus is wired so that part thereof curves in the casing by a length necessary when the cable is brought out accompanied by drawing and revolving of the unit boarding frame.

### SUMMARY OF THE INVENTION

An electrical instrument according to one aspect of an embodiment includes a casing; a drawer portion in which a connection target to which at least one cable is connected is accommodated and which is configured to be drawable outside the casing; and a cable holding portion configured to hold the cable.

### BRIEF DESCRIPTION OF THE DRAWINGS

FIG. 1 is a front view of an inverter according to an embodiment.

FIG. 2 is a cross sectional view taken along the line L-L in FIG. 1.

FIG. 3 is a partial plan cross sectional view of the inverter.

FIG. 4 is an illustration of an internal configuration of the inverter.

FIG. 5 is a plan view showing a state where a cable holding portion of the inverter is contracted.

FIG. 6 is an arrow view in a direction A of FIG. 5.

FIG. 7 is a plan view showing a state where the cable holding portion of the inverter is extended.

FIG. 8 is an arrow view in a direction B of FIG. 7.

### DESCRIPTION OF EMBODIMENTS

Embodiments will be discussed next with reference to the accompanying drawings. It is noted that parts irrelevant to the description may not be shown in the respective drawings in some cases.

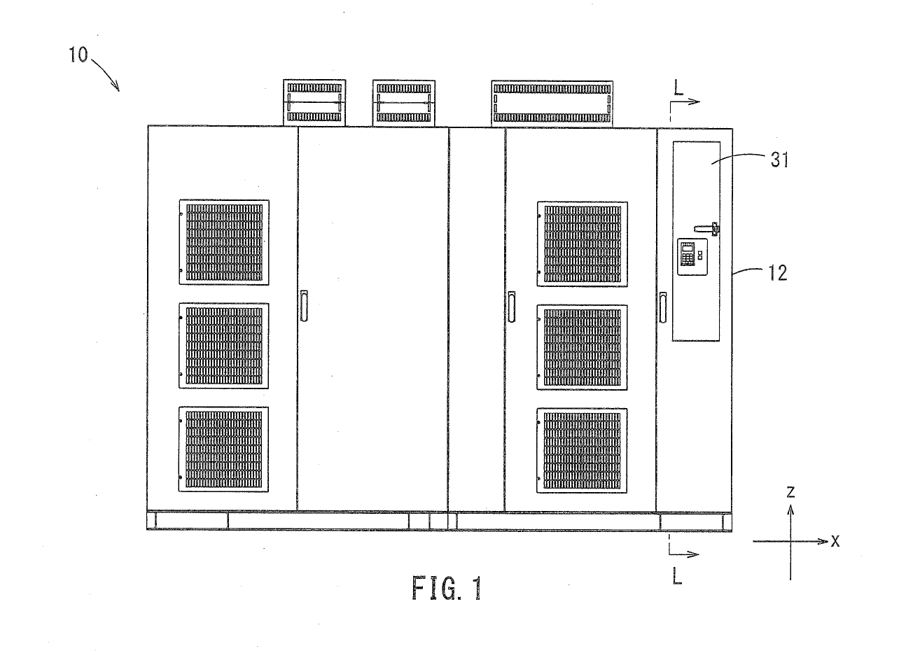

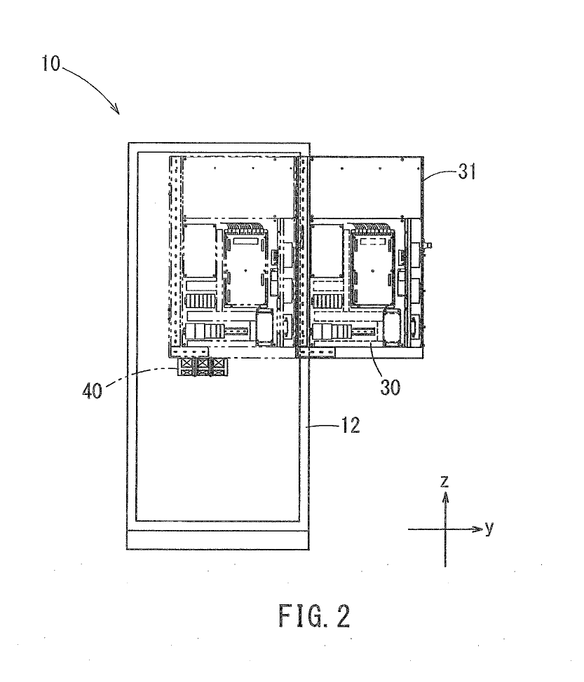

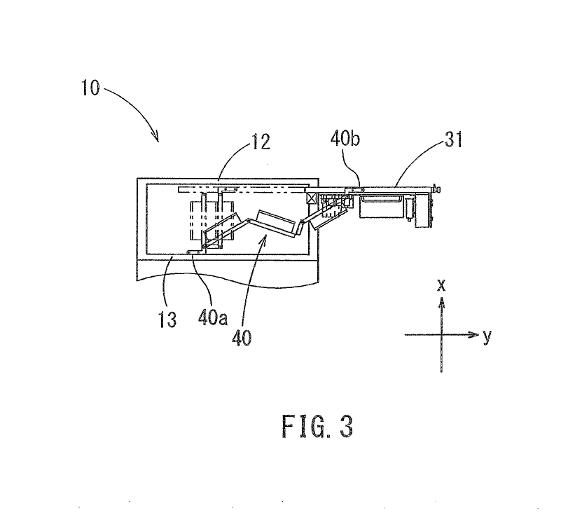

FIGS. 1-3 show an electrical instrument 10 according to one embodiment of. FIG. 1 is a schematic illustration in an x-z plane of the electrical instrument 10 in the present embodiment. FIG. 2 is a schematic illustration of a y-z plane of the electrical instrument 10. FIG. 3 is a schematic illustration of an x-y plane of the electrical instrument 10.

The electrical instrument 10 includes a casing (accommodating means) 12, a drawer portion (drawer means) 31 which accommodates a connection target 30, to which cables are connected, and which is disposed so as to be drawable outside the casing 12, and a cable holding portion (cable holding means) 40 which holds the cables. The cable holding portion 40 determines the position of the cables. As will be described later in detail, it is preferable that the cable holding portion 40 is configured to protect at least part of the cables. The cable holding portion 40 includes a first end part 40a connected to the casing 12 and a second end part 40b connected to the drawer portion 31.

The drawer portion 31 is configured to be drawable from the casing 12 along the y-direction. It is noted that FIG. 2 shows the drawer portion 31 both before and after drawn. However, in order to avoid excessive complexity of the drawing, in FIG. 2, the cable holding portion 40 is shown which is at the position before drawn (accommodated position) from the casing 12.

As indicated by two-dot chain lines in FIGS. 2 and 3, when the drawer portion 31 is at the accommodated position, the cable holding portion 40 is folded in layers so as to be contracted. On the other hand, as indicated by the solid line in FIG. 3, when the drawer portion 31 is drawn out from the accommodated position, the cable holding portion 40 is extended accompanied by drawing of the drawer portion 31. Thus, in the electrical instrument 10 in the present embodiment, the cable holding portion 40 is extended and contracted according to a drawn position of the drawer portion 31 to change the length of the cable holding portion 40 in the direction (y-direction) in which the cable holding portion 40 is drawn. Thus, a load applied to the cables held by the cable holding portion 40 can be reduced.

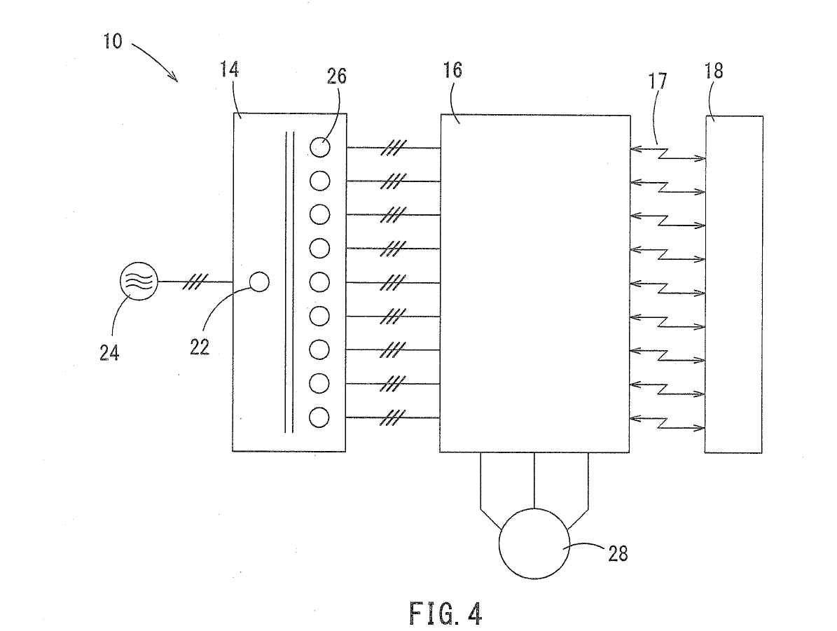

It is noted that the electrical instrument 10 herein is a serial multiple inverter (hereinafter, it may be referred to simply as an “inverter”). The inverter 10 includes, as shown in FIG. 4, an input transformer 14, an electric power conversion section 16, and a control section 18, which are arranged inside the casing 12. The inside of the casing 12 is partitioned by a partition plate 13 (see FIG. 3) extending in the vertical direction (z-direction) into, for example, three compartments in the transverse direction (y-direction). The input transformer 14, the electric power conversion section 16, and the control section 18 are arranged in the respective compartments.

The input transformer 14 is provided with a primary winding 22 on the primary side. To the primary winding 22, a commercial electric power supply (three-phase alternating-current power supply) 24 is connected. On the secondary side of the input transformer 14, for example, first to ninth secondary windings 26 insulated from the first side are provided.

The electric power conversion section 16 can supply a three-phase high voltage power supply with a line voltage of, for example, 3.3 kV or 6.6 kV to an alternating current load 28 of an induction motor or the like. The electric power conversion section 16 includes three cell inverters (not shown) for each output phase, for example.

The control section 18 is connected to the cell inverters of the electric power conversion section 16 through a plurality of optical communication lines 17. The control section 18 transmits a necessary signal through optical communication to each cell inverter to allow the electric power conversion section 16 to perform electric power conversion.

Further, the control section 18 can monitor the voltage, the current, the temperature, etc. at a predetermined point inside each cell inverter with a predetermined frequency through the optical communication.

Here, as shown in FIGS. 2 and 3, in order to increase accommodating efficiency of the inside of the casing 12, the drawer portion 31 in which a control unit (one example of connection target) 30 functioning as the control section 18 is accommodated can be drawn outside from the front of the casing 12 for wiring operation and the like. Specifically, the drawer portion 31 is mounted on a slide rail (not shown) extending in the back-and-forth direction (y-direction) on the right side in the casing 12 to move frontward from the accommodated position.

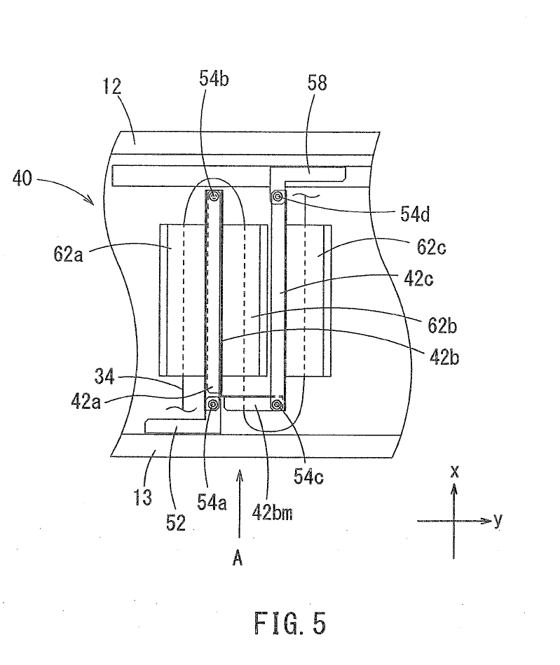

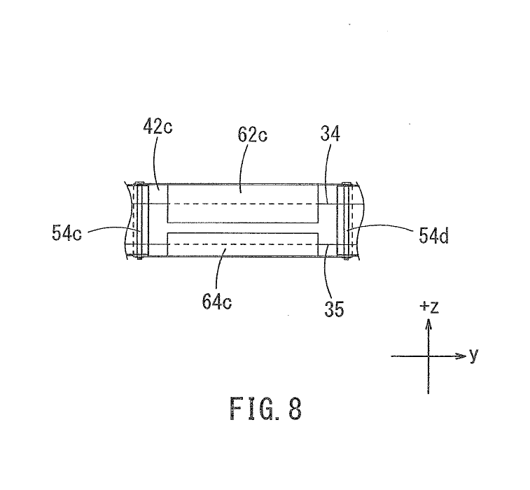

An electrical cable 34 (see FIGS. 5 and 8) and an optical cable 35 (see FIG. 8) as a power supply line, a signal line, or the like, which are connected to the control unit 30, are held by the cable holding portion 40 shown in FIGS. 2 and 3.

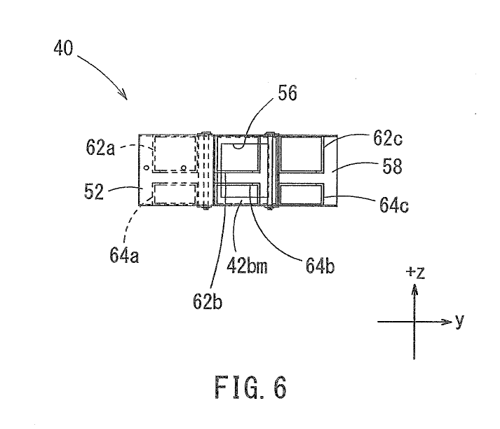

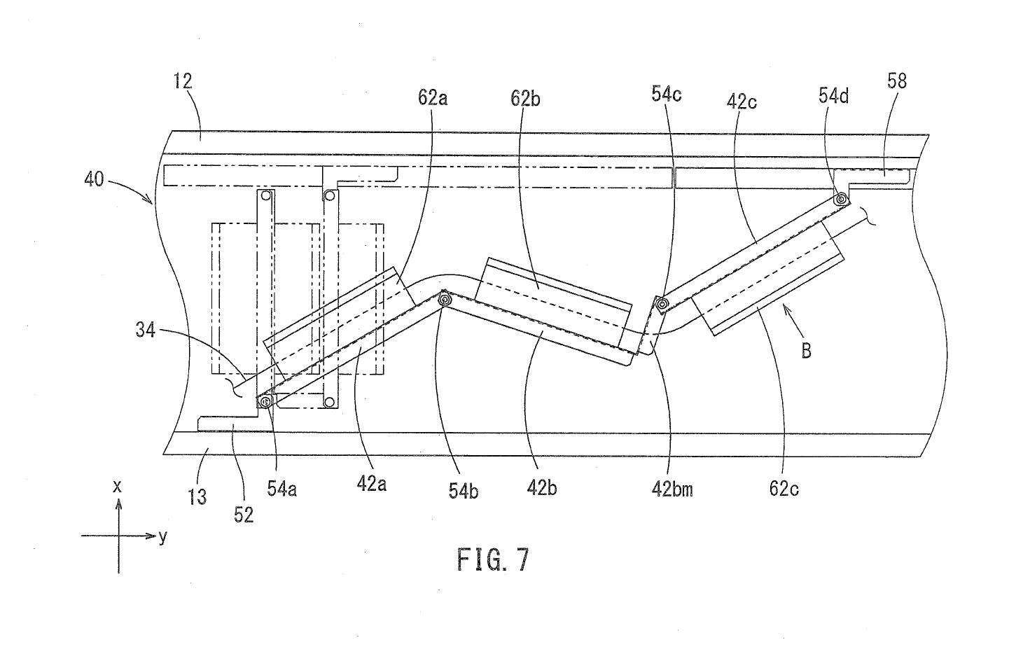

One example of the cable holding portion 40 will be described next in detail with reference to FIGS. 5-8. FIG. 5 is a schematic illustration of the cable holding portion 40 at the accommodated position. FIG. 6 is an arrow view in the direction A of FIG. 5. Further, FIG. 7 is a schematic illustration of the cable holding portion 40 when the drawer portion 31 is drawn out. FIG. 8 is an arrow view in the direction B of FIG. 7.

The cable holding portion 40 includes first to third wired members 42a, 42b, 42c. The wired members (connection members) 42a, 42b, 42c are connected to one another, and provided so as to connect, for example, the lower part (back part of a supporting substrate) of the drawer portion 31 to the partition plate 13 inside the casing 12. The cable holding portion 40 is folded into layers as shown in FIG. 5 when the drawer portion 31 is at the accommodated position. The cable holding portion 40 is extended, as shown in FIG. 7, when the drawer portion 31 is at a drawn position. Thus, the cable holding portion 40 can be extended and contracted according to the position where the drawer portion 31 is drawn.

The first wired member 42a is a plate member, for example. As shown in FIGS. 5 and 7, one end part of the first wired member 42a is mounted, through a first hinge 54a, at a bracket 52 provided at the partition plate 13 inside the casing 12. The first hinge 54a has a first axis extending in the vertical direction (z-direction orthogonal to the direction (y-direction) in which the drawer portion 31 is drawn). This allows the first wired member 42a to rotate about the first axis. It is noted that “orthogonal” herein does not mean strictly orthogonal. That is, “orthogonal” means “substantially orthogonal” with allowance of an error in design or manufacture (hereinafter, the same is applied).

The second wired member 42b is a plate member, for example. The second wired member 42b has one end part folded substantially orthogonally when viewed in plan to form a folded portion 42bm. As shown in FIG. 6, a hole 56 for allowing the electrical cable 34 (see FIGS. 5, 7 and 8) and the optical cable 35 (see FIG. 8) to pass therethrough is formed in the folded portion 42bm.

The other end part of the second wired member 42b is mounted at the other end part of the first wired member 42a through a second hinge 54b. The second hinge 54b has a second axis extending in the vertical direction (z-direction orthogonal to the direction (y-direction) in which the drawer portion 31 is drawn). Accordingly, the second wired member 42b can rotate about the second axis relatively with respect to the first wired member 42a.

The third wired member 42c is a plate member, for example. On end part of the third weird member 42c is mounted at the one end part (the folded portion 42bm) of the second wired member 42b through a third hinge 54c. The third hinge 54c has a third axis extending in the vertical direction (z-direction orthogonal to the direction (y-direction) in which the drawer portion 31 is drawn). Accordingly, the third wired member 42c can rotate about the third axis relatively with respect to the second wired member 42b.

On the other hand, the other end part of the third wired member 42c is mounted, through a fourth hinge 54d, at a bracket 58 fixed at the lower part of the drawer portion 31. The fourth hinge 54d has a fourth axis extending in the vertical direction (z-direction orthogonal to the direction (y-direction) in which the drawer portion 31 is drawn). Accordingly, the third wired member 42c can rotate about the fourth axis relatively with respect to the drawer portion 31.

To the aforementioned first to third wired members 42a, 42b, 42c, first to third first cable ducts 62a-62c and first to third second cable ducts 64a-64c are mounted, respectively. Here, the first to third first cable ducts 62a-62c are arranged above (positive side in z-direction) the first to third second cable ducts 64a-64c, respectively, as shown in FIGS. 6 and 8. Accordingly, the first cable ducts 62a-62c may be referred to as upper cable ducts, while the second cable ducts 64a-64c may be referred to as lower cable ducts. Thus, a plurality of the cable ducts arranged side by side in the direction in which the first to third axes extend are arranged in the first to third wired members 42a, 42b, 42c.

The first upper cable duct 62a and the first lower cable duct 64a are arranged on the back side of the first wired member 42a so that their longitudinal direction accords with the horizontal direction when the cable holding portion 40 is folded in layers (the state where the drawer portion 31 is at the accommodated position), as shown in FIG. 5.

The second upper cable duct 62b and the second lower cable duct 64b are arranged on the front side of the second wired member 42b so that their longitudinal direction accords with the horizontal direction when the cable holding portion 40 is folded in layers.

The third upper cable duct 62c and the third lower cable duct 64c are arranged on the front side of the third wired member 42c so that their longitudinal direction accords with the horizontal direction when the cable holding portion 40 is folded in layers.

The wiring routes of the electrical cable 34 and the optical cable 35 connected to the control unit 30 accommodated in the drawer portion 31 are as follows.

The electrical cable 34 extending from an instrument not shown passes inside the first upper cable duct 62a and extends along the first wired member 42a and the second wired member 42b. Then, the electrical cable 34 passes inside the second upper cable duct 62b, passes through the hole 56 formed in the folded portion 42bm, and then extends along the third wired member 42c. Further, the electrical cable 34 passes inside the third upper cable duct 62c, and then extends over to be connected to the control unit 30 (the drawer portion 31).

The optical cable 35 extending from each cell inverter passes and extends through the first to third lower cable ducts 64a-64c. Except that it passes through the first to third lower cable ducts 64a-64c, the wiring route of the optical cable 35 is the similar to the wiring route of the electrical cable 34. Therefore, the description thereof is omitted.

In this manner, the cables (the electrical cable 34 and the optical cable 35) having different mechanical characteristics (e.g., flexibility) pass through the different ducts 62a-62c and 64a-64c, thereby reducing possibility that a cable strong against a load applied from the outside adversely affects a cable weak therewith. Further, in view of maintenance operation, such as cable exchange, etc., handling the cables is facilitated.

Extension and contraction of the cable holding portion 40 will be described next.

First, when the drawer portion 31 is at the accommodated position, the cable holding portion 40 is folded in layers so that the first to third wired members 42a-42c overlap one another.

Then, when the drawer portion 31 at the accommodated position is drawn out, the bracket 58 provided at the lower part of the drawer portion 31 pulls the third wired member 42c, so that the third wired member 42a pulls the second wired member 42b, thereby causing the second wired member 42b to pull the first wired member 42a. Thus, the first to third wired members 42a-42c move while rotating about the respective axes at their respective end parts (axes of the respective hinges) which extends substantially in parallel to one another, thereby extending the cable holding portion 40.

By contrast, when the drawer portion 31 is returned from the drawn position to the accommodated position, the bracket 58 provided at the lower part of the drawer portion 31 pushes the third wired member 42c, so that the third wired member 42c pushes the second wired member 42b, thereby causing the second wired member 42b to push the first wired member 42a. Thus, the first to third wired members 42a-42c move while rotating about the respective hinges at their respective opposite end parts. In this manner, the cable holding portion 40 is contracted to be folded in layers.

As described above, the cables are routed via the cable holding portion 31 which is extended and contacted according to a drawn position of the drawer portion 31. Thus, even when the drawer portion 31 is drawn largely, a load applied to the cable can be reduced.

It is noted that the present invention is not limited to the above described embodiments and can be changed within the scope that does not change the subject matter of the present invention. For example, the technical scope of the present invention encompasses an invention according to a combination of part or all of the above described embodiments and modified examples.

The number of the wired members is not limited to three. The number of the wired members can be two or more.

Further, an electrical cable and an optical cable are used as the cables 34, 35, respectively. However, the cables are not limited to the optical cable and the electrical cable.

The hinges connecting the wired members has the axes extending in the vertical direction (z-direction). However, the hinges may have axes extending in the horizontal direction, for example. That is, the cable holding portion may be configured to be extended with each wired member rotating about an axis extending in the horizontal direction. In this case, the cable ducts are arranged side by side in the transverse direction when viewed in the direction (y-direction) in which the drawer portion is drawn.

Other examples of the electrical instrument may include a controller for a robot, a controller for a pump, a controller for a machine tool, a controller for a plant, a controller for a disaster monitoring system, etc.

In addition, still further examples of the electrical instrument may include an electronic computer etc. accommodated in a server rack including a drawer portion.

What is claimed is:

1. An electrical instrument, comprising:
a casing;
a drawer portion in which a connection target to which at least one cable is connected is accommodated and which is configured to be drawable outside the casing; and
a cable holding portion configured to hold the cable.

2. The electrical instrument of claim 1, wherein
the cable holding portion is contracted and extended according to a position where the drawer portion is drawn.

3. The electrical instrument of claim 1, wherein
the cable holding portion has a first end part connected to the casing and a second end part connected to the drawer portion.

4. The electrical instrument of claim 1, wherein
the cable holding portion includes a plurality of wired members connected to each other through a hinge rotating about an axis orthogonal to a direction in which the drawer portion is drawn so that the cable holding portion is capable of being folded in layers, and
of the plurality of wired members, a wired member located on the side of one end part of the cable holding portion is connected to the casing, while a wired member located on the side of the other end part of the cable holding portion is connected to the drawer portion.

5. The electrical instrument of claim 1, wherein
the cable holding portion includes:
a first wired member having one end part which is mounted at the casing rotatably about a first axis orthogonal to a direction in which the drawer portion is drawn;
a second wired member having one end part mounted at the other end part of the first wired member rotatably about a second axis in parallel to the first axis; and
a third wired member having one end part mounted at the other end part of the second wired member rotatably about a third axes in parallel to the first axis and the other end part mounted at the drawer portion rotatably about a fourth axis in parallel to the first axis.

6. The electrical instrument of claim 5, wherein
each of the first to third wired members includes a cable duct, and
the cable is arranged inside the cable duct.

7. The electrical instrument of claim 5, wherein
each of the first to third wired members includes a first cable duct and a second cable duct,
the at least one of the cables includes a first cable passing through the first cable duct of each of the first to third wired members and a second cable passing through the second cable duct of each of the first to third wired members, and
the first cable and the second cable are different from each other in mechanical characteristic.

8. The electrical instrument of claim 7, wherein
the first cable is an optical cable, while the second cable is an electrical cable.

9. An electrical instrument, comprising:
an accommodating means;
a drawer means in which a connection target to which at least one cable is connected is accommodated and which is configured to be drawable outside the accommodating means; and
a cable holding means for holding the cable.
